(19) United States
(12) Patent Application Publication
(10) Pub. No.: US 2021/0391500 A1
(43) Pub. Date: Dec. 16, 2021

(54) OPTOELECTRONIC DEVICE, ASSOCIATED DISPLAY SCREEN AND METHOD FOR FABRICATING SUCH AN OPTOELECTRONIC DEVICE

(71) Applicant: ALEDIA, Echirolles (FR)

(72) Inventors: Pamela RUEDA FONSECA, FONTAINE (FR); Tiphaine DUPONT, GRENOBLE (FR); Wei Sin TAN, MEYLAN (FR)

(21) Appl. No.: 17/287,002

(22) PCT Filed: Oct. 21, 2019
(86) PCT No.: PCT/EP2019/078603

§ 371 Date: Apr. 20, 2021

(30) Foreign Application Priority Data
Oct. 22, 2018 (FR) 1859722

(51) Int. Cl. H01L 33/24; H01L 27/15; H01L 33/38; H01L 27/14; H01L 33/00; H01L 33/46

(52) U.S. Cl. CPC H01L 33/24; H01L 27/156; H01L 33/38; H01L 2933/0025; H01L 33/005; H01L 33/46; H01L 27/14

(57) ABSTRACT

Disclosed is an optoelectronic device including a substrate and at least two sub-pixels, each sub-pixel being adapted to emit a respective first radiation, the substrate, each sub-pixel including: at least one fin made of a first semiconductor material, the fin along a normal direction perpendicular to the substrate, each fin having a first lateral side; and a covering layer including one or several radiation-emitting layer, the covering layer extending on the first lateral side of each fin. The sub-pixels delimit a recess located between both sub-pixels, and a blocking structure being interposed between both sub-pixels in the recess, the blocking structure being adapted to prevent the first radiation emitted by a sub-pixel to reach the other sub-pixel through the blocking structure.

### CROSS-REFERENCE TO RELATED APPLICATIONS

This application is the U.S. national phase of International Application No. PCT/EP2019/078603 filed Oct. 21, 2019 which designated the U.S. and claims priority to FR 1859722 filed Oct. 22, 2018, the entire contents of each of which are hereby incorporated by reference.

### FIELD OF THE INVENTION

The present invention concerns an optoelectronic device. The present invention also concerns a display screen comprising a set of such optoelectronic devices and a method for fabricating such an optoelectronic device.

### BACKGROUND OF THE INVENTION

Optoelectronic devices comprising an ensemble of light emitters, each of them emitting a different light (i.e emitting light having a different wavelength), are used in a great number of devices such as a display screen. By controlling which light emitter of which optoelectronic device emits light at any given moment, images are formed onto the display screen. Such optoelectronic devices are thus usually called “pixels”, short for “picture element”, and the individual light emitters are called “sub-pixels”.

Sub-pixels are often fabricated using semiconductor structures, which may be efficiently controlled by simply turning on or off a supply electrical current, and which may provide good overall emission efficiency (also called “wall-plug efficiency”). In some cases, each semiconductor structure of a single optoelectronic device may emit a light having a different color than the other semiconductor structures. In other cases, each semiconductor structure emits a same light, but some sub-pixels may include a radiation converter able to convert the light emitted by the semiconductor structure into a light having a different wavelength.

In order to improve the spatial resolution of the display screens, or to reduce the size of the display screen while keeping the number of pixels constant, it is known to reduce the size of the pixels.

However, when sub-pixels are placed in close vicinity on a substrate, optical cross-talk may occur where at least a portion of the light emitted by one first sub-pixel may reach a second sub-pixel and either exit through this second sub-pixel—thus giving a viewer the impression that the first sub-pixel is bigger than the first sub-pixel really is and therefore reducing the spatial resolution—or be absorbed by the radiation converter of the second sub-pixel. This may also result in the emission of some light having an undesired wavelength.

### SUMMARY OF THE INVENTION

There is therefore a need for an optoelectronic device having a reduced cross-talk between sub-pixels even when the dimensions of the optoelectronic device are reduced.

For this, the present description concerns an optoelectronic device comprising a substrate and at least two sub-pixels, each sub-pixel being adapted to emit a respective first radiation, the substrate having a support face, each sub-pixel comprising:
at least one fin made of a first semiconductor material, the first material having a first bandgap value, the fin extending from the support face along a normal direction perpendicular to the support face, each fin having a superior side, a first lateral side and a second lateral side, each lateral side extending between the superior side and the substrate,
a covering layer comprising one or several radiation-emitting layer(s), the covering layer extending on the first lateral side of each fin, each radiation-emitting layer being made of a second semiconductor material, the second semiconductor material having a second bandgap value, the second bandgap value being strictly inferior to the first bandgap value,
   the sub-pixels delimiting a recess, the recess being located between both sub-pixels, and a blocking structure made of a third material being interposed between both sub-pixels in the recess, the blocking structure being adapted to prevent the first radiation emitted by a sub-pixel to reach the other sub-pixel through the blocking structure.

According to specific embodiments, the optoelectronic device comprises one or several of the following features, taken separately or according to any possible combination:

at least one of the following properties is fulfilled:
the first semiconductor material has a first type of doping chosen among n-doping and p-doping, the covering layer further comprising a doped layer, each radiation-emitting layer(s) being interposed between the fin and the doped layer, the doped layer being made of a third semiconductor material having a third bandgap value, the third bandgap value being strictly greater than the second bandgap value, the third semiconductor material having a second type of doping chosen among n-doping and p-doping, the second type of doping being different from the first type of doping,
the optoelectronic device comprises a control circuit and, for at least one sub-pixel, an electrode connecting the sub-pixel and the control circuit through the substrate, and
at least one sub-pixel comprises a first barrier layer made of an electrically insulating material, the first barrier layer forming a barrier between the substrate and the covering layer;

each fin of each sub-pixel delimits at least partially a cavity in a plane perpendicular to the normal direction;

the intersections of the each fin of one sub-pixel with the support face forming a closed contour on the support face, the cavity being surrounded by the fin in a plane perpendicular to the normal direction;

the contour is chosen among a triangle, a square, a rectangle and a hexagon;

each first radiation comprises a first set of electromagnetic waves, the radiation-emitting layer of at least one sub-pixel being configured to emit a second radiation comprising a second set of electromagnetic waves, the optoelectronic device further comprising a radiation converter configured to convert the second radiation into the respective first radiation, a wavelength being defined for each electromagnetic wave, the first set corresponding to a first range of wavelengths and the second set corresponding to a second range of wavelengths, the first range having a first mean wavelength and the second range having a second mean wavelength, the first mean wavelength being different from the second mean wavelength, the radiation converter being contained in the cavity of the sub-pixel considered;

the blocking structure is adapted to reflect the base radiation of each sub-pixel;

the substrate comprises a semiconductor structure configured to emit a third radiation comprising a third set of electromagnetic waves, a wavelength being defined for each electromagnetic wave, the first set corresponding to a first range of wavelengths and the third set corresponding to a third range of wavelengths, the first range having a first mean wavelength and the third range having a third mean wavelength, the first mean wavelength being strictly inferior to the third mean wavelength, the semiconductor structure and at least one sub-pixel being aligned along the normal direction;

at least one of the following properties is fulfilled:
each covering layer is in contact with at least ninety percent of the surface of the first lateral side of the fin,
the third material is a metal, and
the third material is aluminum;

the blocking structure is adapted to reflect the first radiation of each sub-pixel;

each covering layer has a top portion in contact with the superior side and a first portion in contact with the first lateral side;

at least one blocking structure has a top layer made of the third material, the top portion being interposed between the superior side of the fin and the top layer, the top layer covering entirely the top portion of the covering layer;

each first radiation comprises a first set of electromagnetic waves, the top portion of the radiation-emitting layer being configured to emit a fourth radiation comprising a fourth set of electromagnetic waves, a wavelength being defined for each electromagnetic wave, the first set corresponding to a first range of wavelengths and the fourth set corresponding to a fourth range of wavelengths, the first range having a first mean wavelength and the fourth range having a fourth mean wavelength, the first mean wavelength being different from the fourth mean wavelength; and

each covering layer has a second portion covering at least partially the second lateral side of the corresponding fin, and the blocking structure comprises an electrically insulating layer configured to electrically isolate at least one sub-pixel from the blocking structure.

A display screen comprising a set of optoelectronic devices as previously defined is also proposed.

The present description also concerns a method for fabricating an optoelectronic device, the method comprising steps for:
supplying a substrate having a support face, and
fabricating two emitters, each sub-pixel being adapted to emit a corresponding first radiation, each sub-pixel comprising:
   at least one fin made of a first semiconductor material, the first material having a first bandgap value, the fin extending from the support face along a normal direction perpendicular to the support face, each fin having a superior side, a first lateral side and a second lateral side, each lateral side extending between the superior side and the substrate, and
   a covering layer comprising one or several radiation-emitting layer(s), the covering layer extending on the first lateral side of each fin, each radiation-emitting layer being made of a second semiconductor material, the second semiconductor material having a second bandgap value, the second bandgap value being strictly inferior to the first bandgap value,

both sub-pixels delimiting a recess between both sub-pixels the method further comprising a step for depositing, in the recess, a third material so as to form a blocking structure adapted to prevent the first radiation emitted by a sub-pixel to reach the other sub-pixel through the blocking structure.

According to specific embodiments, the method for fabricating an optoelectronic device comprises one or several of the following features, taken separately or according to any possible combination:

the step for fabricating two sub-pixels comprises steps for:
fabricating one ridge made of the first semiconductor material, the ridge extending from the support face along the normal direction, the ridge having a superior side and two first lateral sides,
depositing the covering layer on at least the two first lateral sides of the ridge, and
forming the fins and the recess by etching away at least a portion of the ridge;

the step for fabricating two sub-pixels comprises steps for:
forming a core made of a fourth material, the core extending from the support face along the normal direction, the core having a superior face and lateral flanks extending between the substrate and the superior face,
depositing a layer of the first material and at least one layer of the second material on at least a portion of the lateral flanks to form at least one fin and the corresponding covering layer, and
removing the fourth material;

the step for fabricating two sub-pixels comprises steps for:
fabricating the fin of each sub-pixel, and
depositing on each fin at least one layer of the second material to form the covering layer;

the method comprises at least one of the following steps:
depositing, onto the covering layer of at least one sub-pixel, a layer of transparent electrically conductive material;
depositing onto the support face a first barrier layer made of electrically insulating material, the first barrier layer forming a barrier between the covering layer and the substrate, and
before depositing the third material, depositing in the recess an electrically insulating material so as to form a second barrier layer made of electrically insulating material onto at least one sub-pixel, the second barrier layer forming a barrier between the third material and the sub-pixel.

### BRIEF DESCRIPTION OF THE DRAWINGS

Features and advantages of the invention will be made clear by the following specification, given only as a non-limiting example, and making a reference to the annexed drawings, on which:

FIG. 1 is a schematic partial side cut-away view of a display screen comprising a set of optoelectronic devices,

FIG. 2 is a schematic partial side cut-away view of a structure resulting of some steps of a method for fabricating an optoelectronic device of FIG. 1,

FIG. 3 is a schematic partial side cut-away view of a structure resulting of some ulterior steps of the method of FIG. 2,

FIG. 4 is another schematic partial side cut-away view of a structure resulting of some later steps, posterior to the steps of FIG. 3, of the method of FIG. 2,

FIG. 5 is a scheme of two optoelectronic devices viewed laterally in a section along the line V-V on FIG. 6,

FIG. 6 is a schematic top view of two optoelectronic devices,

FIG. 7 is a schematic partial side cut-away view of a structure resulting of some steps of a method for fabricating the optoelectronic devices of FIG. 5,

FIG. 8 is a schematic partial side cut-away view of a structure resulting of some ulterior steps of the method leading to the structure of FIG. 7,

FIG. 9 is a schematic partial top view of the structure of FIG. 8,

FIG. 10 is a schematic partial side cut-away view of a structure resulting of some later steps of the method leading to the structures of FIG. 7 to 9,

FIG. 11 is a schematic partial side cut-away view of an optoelectronic device fabricated using the method leading to the structures of FIGS. 7 to 10,

FIG. 12 is a schematic partial side cut-away view of a structure resulting of some steps of another method for fabricating the optoelectronic devices of FIG. 5,

FIG. 13 is a schematic partial side cut-away view of a structure resulting of some later steps of the method leading to the structure of FIG. 12, and

FIG. 14 is a schematic partial side cut-away view of a structure resulting of some steps, posterior to the steps of FIG. 13, of the method leading to the structures of FIGS. 12 and 13.

### DETAILED DESCRIPTION OF PREFERRED EMBODIMENTS

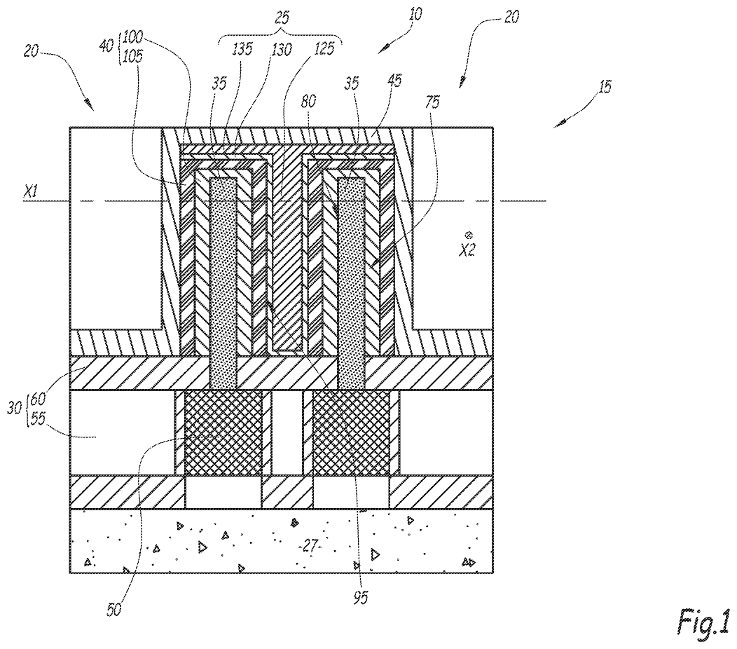

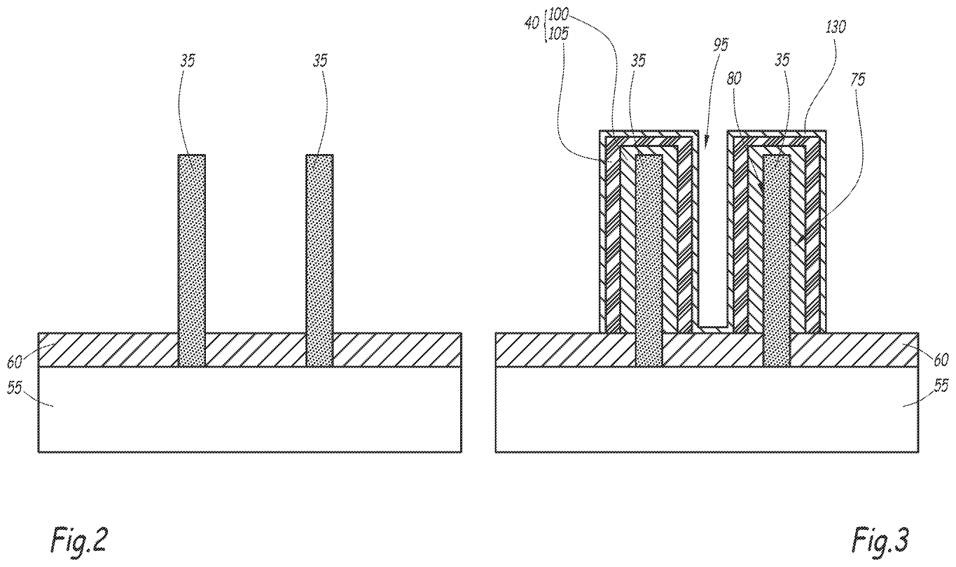

A first example of display screen 10 is partially shown on FIGS. 1 and 2.

The display screen 10 is, for example, integrated in an electronic device such as a mobile phone, a tablet or a laptop computer. In another embodiment, the display screen 10 is integrated in dedicated display device such as a television set or a desktop computer screen.

The display screen 10 is configured for displaying a set of images.

The display screen 10 comprises a set of optoelectronic devices 15.

It should be noted that the number of optoelectronic devices 15 may vary. Each optoelectronic device 15, also called “picture element”, or in short “pixel” is configured for emitting at least one radiation.

For example, each optoelectronic device 15 is configured to emit one of a set of radiations comprising a first radiation, a second radiation and a third radiation. In an embodiment, each optoelectronic device 15 is configured to emit one of a set of radiations comprising a first radiation, a second radiation, a third radiation and a fourth radiation.

It should be noted that each optoelectronic device 15 may be used as a single light source outside of a display screen.

Each radiation comprises a set of electromagnetic waves.

Each set corresponds to a range of wavelengths. The range of wavelengths is the group formed by all the wavelengths of the set of electromagnetic waves.

The first radiation comprises a first set of electromagnetic waves.

The first set of electromagnetic waves corresponds to a first range of wavelengths.

A first mean wavelength is defined for the first range of wavelengths.

A mean wavelength equal to half of the sum of the largest and the smallest wavelengths of the first range of wavelengths is an example of first mean wavelength.

The first radiation is, for example, a blue radiation. A first radiation whose first mean wavelength is comprised between 430 nanometers (nm) and 490 nm is an example of blue radiation.

The second radiation is different from the first radiation.

The second radiation comprises a second set of electromagnetic waves.

The second set of electromagnetic waves corresponds to a second range of wavelengths.

A second mean wavelength is defined for the second range of wavelengths. A mean wavelength equal to half of the sum of the largest and the smallest wavelengths of the second range of wavelengths is an example of second mean wavelength.

The second mean wavelength is, in an embodiment, different from the first mean wavelength.

The second radiation is, for example, a green radiation. A second radiation whose second mean wavelength is comprised between 500 nm and 570 nm is an example of green radiation.

Each third radiation is, for example, different from the first radiation and the second radiation.

Each third radiation comprises a third set of electromagnetic waves.

Each third set of electromagnetic waves corresponds to a third range of wavelengths.

A third mean wavelength is defined for each third range of wavelengths. A mean wavelength equal to half of the sum of the largest and the smallest wavelengths of the third range of wavelengths is an example of third mean wavelength.

The third mean wavelength is, for example, strictly superior to at least one of the first mean wavelength and the second mean wavelength.

In an embodiment, the third mean wavelength is strictly superior to both the first mean wavelength and the second mean wavelength.

One of the third radiations is, for example, a red radiation. For example, the corresponding third mean wavelength is comprised between 600 nm and 720 nm.

When the optoelectronic device is configured to emit four different radiations, the fourth radiation is a yellow radiation. For example, the fourth radiation has a fourth mean wavelength comprised between 570 nm and 600 nm.

Each optoelectronic device 15 comprises at least two sub-pixels 20, a blocking structure 25 and a control circuit 27. In an embodiment, each optoelectronic device comprises three sub-pixels 20.

In an embodiment, each optoelectronic device 15 further comprises, for at least one emitter 20, a radiation converter 22. For example, each optoelectronic device 15 comprises a radiation converter 22 for each emitter 20.

Each sub-pixel 20 is configured to emit one radiation among the first radiation, the second radiation, the third radiation and the fourth radiation.

In a variant, each optoelectronic device 15 comprises four sub-pixels 20. In this variant, one of the sub-pixels 20 is configured to emit the fourth radiation.

Each sub-pixel 20 comprises a substrate 30, one fin 35, a covering layer 40, a first electrode 45 and a second electrode 50.

FIG. 1 shows an example of sub-pixel 20 comprising one fin 35. However, embodiments wherein each sub-pixel 20 comprises several fins 35 may be envisioned.

The substrate 30 is common to each sub-pixel 20 of the optoelectronic device 15. For example, the substrate 30 is common to all sub-pixels 20 of the display screen 10.

A normal direction D is defined for the substrate 30. The substrate 30 is perpendicular to the normal direction D. In particular, the substrate 30 has a support face 53 that is perpendicular to the normal direction D.

The substrate 30 comprises a support plate 55 and a first barrier layer 60.

The support plate 55 is delimited along the normal direction D by the support face 53.

The support plate 55 is made of a substrate material. The substrate material is, for example, a semiconductor material.

A substrate bandgap value is defined for the substrate material.

The expression “bandgap value” shall be understood as meaning the value of the forbidden band between the valence band and the conduction band of the material.

The bandgap value is, for example, measured in electron-volts (eV).

The valence band is defined as being, among the energy bands which are allowed for electrons in the material, the band that has the highest energy while being completely filled at a temperature inferior or equal to 20 Kelvin (K).

A first energy level is defined for each valence band. The first energy level is the highest energy level of the valence band.

The conduction band is defined as being, among the energy bands which are allowed for electrons in the material, the band that has the lowest energy while not being completely filled at a temperature inferior or equal to 20 K.

A second energy level is defined for each conduction band. The second energy level is the highest energy level of the conduction band.

Thus, each bandgap value is measured between the first energy level and the second energy level of the material.

A semiconductor material is a material having a bandgap value strictly superior to zero and inferior or equal to 6.5 eV.

The substrate material is, for example, silicon.

In other possible embodiments, the substrate material is another semiconductor material such as a III-nitride material. III-nitride materials are a group of materials comprising GaN, AlN and InN and the alloys of GaN, AlN and InN.

According to an embodiment, the substrate material is GaN.

Embodiments wherein the substrate material is an electrically insulating material such as sapphire may also be envisioned.

Doping is defined as the presence, in a material, of impurities bringing free charge carriers. Impurities are, for example, atoms of an element that is not naturally present in the material.

When the impurities increase the volumic density of holes in the material, with respect to the undoped material, the doping is p-type. For example, a layer of GaN is p-doped by adding magnesium (Mg) atoms.

When the impurities increase the volumic density of free electrons in the material, with respect to the undoped material, the doping is n-type. For example, a layer of GaN is n-doped by adding silicon (Si) atoms.

The substrate material is, for example, n-doped. However, the type of doping may vary in some embodiments.

The support plate 55 delimits, for each sub-pixel 20, at least one passage 65 traversing the substrate 30 along the normal direction D. Each passage 65 is configured to contain at least a portion of a second electrode 50.

Each passage 65 has lateral walls delimiting the passage 65 in a plane perpendicular to the normal direction D.

In a specific embodiment, the support plate 55 includes a two-dimensional structure.

A stack of semiconductor layers stacked along the normal direction D is an example of two-dimensional structure.

The two-dimensional structure is, for example, a LED structure. A LED structure, also called “light-emitting diode structure” is a semiconductor structure comprising several semiconductor areas forming a P-N junction and configured to emit light when an electrical current flows through the different semiconductor areas.

A two-dimensional semiconductor structure comprising an n-doped layer, a p-doped layer and at least one radiation-emitting layer stacked along the normal direction D is an example of LED structure. In this case, each one radiation-emitting layer is interposed between the n-doped layer and the p-doped layer.

The two-dimensional LED structure and the sub-pixel 20 are aligned along the normal direction D. In other words, at least a portion of the two-dimensional LED structure is situated underneath the sub-pixel 20 when the sub-pixel 20 is on the top of the support plate 55.

The two-dimensional LED structure is electrically connected to the control circuit 27.

The radiation-emitting layer or layers of the two-dimensional semiconductor structure are, for example, configured to emit a fifth radiation.

The fifth radiation comprises a fifth set of electromagnetic waves.

The fifth set of electromagnetic waves corresponds to a fifth range of wavelengths.

A fifth mean wavelength is defined for the fifth range of wavelengths.

The fifth mean wavelength is strictly superior to the first mean wavelength. For example, each fifth radiation is a red radiation.

The first barrier layer 60 is made of an electrically insulating material. For example, the first barrier layer 60 is made of SiO₂ or silicon nitride.

The first barrier layer 60 is configured to electrically insulate each fin 35 from the support plate 55.

The first barrier layer 60 forms a barrier between the support plate 55 and the covering layer 40. In particular, the first barrier layer 60 is configured to electrically insulate each covering layer 40 from the support plate 55.

The first barrier layer 60 covers, for example, entirely the support face 53, except in the locations where a passage 65 opens onto a surface of the support plate 55.

In an embodiment, the first barrier layer 60 further covers at least the lateral walls of each passage 65 so that the first barrier layer 60 electrically insulates the second electrode 50 contained in the passage 65 from the support plate 55.

Each fin 35 extends from the support face 53 along the normal direction D.

The expression “fin” shall be understood as encompassing any thin structure extending along the normal direction D, along another direction perpendicular to the normal direction D. A fin has a height measured along the normal direction D, has a length measured along the other direction and a thickness measured along a direction perpendicular to both of those directions, the thickness being inferior or equal to both the length and the height. For example, the thickness is inferior or equal to half the length and to half the height.

A ratio between the height and the thickness is, for example, comprised between 1 and 50. In an embodiment, the ratio is comprised between 1 and 10.

The expression “comprised between” two values shall be understood as encompassing those values. The example, a ratio comprised between 1 and 50 is superior or equal to 1 and inferior or equal to 50.

An example of fin 35 is a parallelepiped having a superior side 70 perpendicular to the normal direction D.

The expression “perpendicular” shall be understood as corresponding to two directions having between them an angle comprised between 80 degrees (°) and 100° for example equal to 90°.

The height is measured along the normal direction D between the substrate 30 and the superior side 70.

The fin 35 has a first lateral side 75, a second lateral side 80 and two extreme sides.

Each lateral side 75, 80 extends between the superior side 70 and the substrate 30.

A first direction X1 is defined for each fin 35. The first direction X1 is perpendicular to the normal direction D.

Both lateral sides 75, 80 are perpendicular to the first direction X1.

Both extreme sides are perpendicular to a second direction X2 perpendicular to both the normal direction D and the first direction X1.

Another example of fin 35 is a portion of annular ring. In this case, both lateral sides 75, 80 are perpendicular to the substrate 30 and parallel to one another. The intersection of each lateral side 75, 80 with the substrate 30 is a portion of a circle.

Each fin 35 of each sub-pixel 20 is, for example, identical to the fins 35 of the other sub-pixels 20.

A recess 95 is interposed between two fins 35 belonging each to a corresponding sub-pixel 20.

Among the first and second lateral sides, the first lateral side 75 is the lateral side which is furthest from the recess 95 in a plane perpendicular to the normal direction D. For example, the first lateral side 75 faces away from the recess 95 while the second lateral side 80 faces the recess 95.

The height is comprised between 100 nanometers (nm) and 50 micrometers (μm). For example, the height is comprised between 1 μm and 20 μm.

It should be noted that the superior side 70 of each fin 35 is, in some embodiments, not perpendicular to the normal direction D.

The thickness is measured between the first lateral side 75 and the second lateral side 80.

The thickness is measured in a plane perpendicular to the normal direction D. For example, the thickness is measured along the first direction X1.

The thickness is comprised between 100 nm and 10 μm. For example, the thickness is comprised between 500 nm and 2 μm.

Each fin 35 is made of a first semiconductor material. The first semiconductor material has a first bandgap value.

The first semiconductor material is, for example, GaN.

The first semiconductor material has a first type of doping chosen among p-doping and n-doping. The first semiconductor material is, for example n-doped.

Each covering layer 40 comprises at least one radiation-emitting layer 100 and a doped layer 105.

Each covering layer 40 is in contact with the first lateral side 75 of each fin 35. In particular, each covering layer 40 extends on the first lateral side 75.

In an embodiment, each covering layer 40 has a first portion 110, a second portion 115 and a top portion 120.

However, embodiments wherein the sub-pixel 20 is deprived of one or both portions among the second portion 115 and the top portion 120 may be considered.

The first portion 110 is in contact with the first lateral side 75.

In particular, the first portion 110 extends on the first lateral side 75. For example, each layer of the first portion 110 is perpendicular to the first direction X1.

The first portion 110 covers, in an embodiment, at least half of the surface of the first lateral side 75. For example, the first portion 110 covers at least 90 percents (%) of the surface of the first lateral side 75.

The second portion 115 is in contact with the second lateral side 80.

In particular, the second portion 115 extends on the first second lateral side 80. For example, each layer of the second portion 115 is perpendicular to the first direction X1.

The second portion 115 is interposed between the second lateral side 80 and the recess 95.

The second portion 115 covers, in an embodiment, at least half of the surface of the second lateral side 80. For example, the second portion 115 covers at least 90% of the surface of the second lateral side 80.

The top portion 120 is in contact with the top side 70.

In particular, the top portion 120 extends on the top side 70. For example, each layer of the top portion 120 is perpendicular to the normal direction D.

The top portion 120 is interposed between the top side 70 and the first electrode 45.

The top portion 120 covers, in an embodiment, at least half of the surface of the top side 70. For example, the top portion 120 covers entirely the top side 70.

Each radiation-emitting layer 100 is interposed between the fin 35 and the doped layer 105.

For example, the covering layer 40 comprises a stack of radiation-emitting layers 100 interposed between the fin 35 and the doped layer 105.

Each radiation-emitting layer 100 is made of a second semiconductor material.

The second semiconductor material has a second bandgap value strictly inferior to the bandgap value of the first material.

The emitting layer is, for example, undoped. In other embodiments, the emitting layer is doped.

Each radiation-emitting layer 100 is, for example, a quantum well or a stack of quantum wells.

A quantum well is a specific example of emitting layer having a lower bandgap value than bandgap values of the n-doped and p-doped layers. A quantum well is a structure in which quantum confinement occurs, in one direction, for at least one type of charge carriers. The effects of quantum confinement take place when the dimension of the structure along that direction becomes comparable to or smaller than the de Broglie wavelength of the carriers, which are generally electrons and/or holes, leading to energy levels called “energy subbands”.

In such a quantum well, carriers may have only discrete energy values but are, usually, able to move within a plane perpendicular to the direction in which the confinement occurs. The energy values available to the carriers, also called “energy levels”, increase when the dimensions of the quantum well decrease along the direction in which the confinement occurs.

In quantum mechanics, the “de Broglie wavelength”, is the wavelength of a particle when the particle is considered as a wave. The de Broglie wavelength of electrons is also called “electronic wavelength”. The de Broglie wavelength of a charge carrier depends of the material of which the quantum well is made.

An example of quantum well is an emitting layer having a thickness strictly inferior to the product of the electronic wavelength of the electrons in the semiconductor material of which the emitting layer is made with five.

Another example of quantum well is an emitting layer having a thickness strictly inferior to the product of the de Broglie wavelength of excitons in the semiconductor material of which the emitting layer is made with five. An exciton is a quasiparticle comprising an electron and a hole.

In particular, the thickness of each radiation-emitting layer 100 is, for any point of the radiation-emitting layer 100, comprised between 1 nm and 200 nm.

The thickness of each radiation-emitting layer 100 is measured, for any point of the radiation-emitting layer 100, along a direction perpendicular to the surface of the fin 35 at the point of the surface of the fin 35 that is the closest to the point of the radiation-emitting layer 100 considered.

For example, the thickness of each radiation-emitting layer 100 in a point of the radiation-emitting layer 100 that is aligned with a point of the fin 35 along the normal direction D is measured along the normal direction D. The thickness of each radiation-emitting layer 100 in a point of the radiation-emitting layer 100 which is aligned in a plane perpendicular to the normal direction with a point of the fin 35 is measured along a direction perpendicular to the nearest side 70, 75 and 80 of the fin 35.

Each radiation-emitting layer 100 is, for example, made of InGaN.

Each radiation-emitting layer 100 is configured to emit a base radiation.

The base radiation is, for example, chosen among the first, second, third and fourth radiation.

In an embodiment, the base radiation is different from each of the first, second, third and fourth radiation.

Each base radiation comprises a base set of electromagnetic waves.

Each base set of electromagnetic waves corresponds to a base range of wavelengths.

A base mean wavelength is defined for each base range of wavelengths. A mean wavelength equal to half of the sum of the largest and the smallest wavelengths of the base range of wavelengths is an example of base mean wavelength.

The base mean wavelength is, for example, strictly inferior to at least one of the first, second and third mean wavelengths.

In an embodiment, the base mean wavelength is strictly inferior to each of the first, second and third mean wavelengths.

The base radiation is, for example, a blue radiation. In a variant, the base radiation is a ultraviolet radiation. An ultraviolet radiation is an electromagnetic wave having a wavelength comprised between 10 nm and 420 nm, for example comprised between 200 nm and 420 nm.

In an embodiment, the portion of each radiation-emitting layer(s) 100 that is contained in the first portion 110 is configured to emit the corresponding base radiation. For example, the portions of each radiation-emitting layer(s) 100 which are contained in the first portion 110 and the second portions 115 are both configured to emit the corresponding base radiation.

In an embodiment, the portion of each radiation-emitting layer(s) 100 which is contained in the top portion 120 is configured to emit a top radiation.

The top radiation comprises a top set of electromagnetic waves.

Each top set of electromagnetic waves corresponds to a top range of wavelengths.

A top mean wavelength is defined for each top range of wavelengths. A mean wavelength equal to half of the sum of the largest and the smallest wavelengths of the top range of wavelengths is an example of top mean wavelength.

The top mean wavelength is, for example, strictly superior to the corresponding base wavelength.

For example, each radiation-emitting layer 100 is a quantum well and the thickness of each radiation-emitting layer 100 is strictly superior in the top portion 120 than in any portion of the first and second portions 110, 115.

The doped layer 105 is made of a third semiconductor material having a third bandgap value. The third bandgap value is strictly superior to the second bandgap value.

The doped layer 105 is, for example, made of GaN.

The doped layer 105 covers at least partially the radiation-emitting layer or layers 100.

The doped layer 105, each radiation-emitting layer(s) 100 and the fin 35 form a LED structure.

The doped layer 105 plays the role of a n-doped layer or of a p-doped layer of the LED structure.

The type of doping (n or p) of the doped layer 105 is different from the first type of doping (p or n) in the fin 35. For example, the doped layer 105 is p-doped. In this case, the fin 35 plays the role of n-doped layer in the LED structure.

In other embodiments, the fin 35 plays the role of p-doped layer and the doped layer 105 plays the role of n-doped layer.

The recess 95 is delimited, in a plane perpendicular to the normal direction D, by two sub-pixels 20.

The recess 95 is interposed between both sub-pixels 20.

The recess 95 is, for example, delimited along the first direction X1 by the doped layers 105 of the fins 35 of the sub-pixels 20.

The recess 95 is delimited along the normal direction D by the substrate 30.

A width is defined for the recess 95. The width is measured in a plane perpendicular to the normal direction D between both fins 35 that delimit the recess 95.

The width of the recess 95 is, for example, comprised between 100 nm and 10 μm.

The recess 95 contains at least partially the blocking structure 25.

Each radiation converter 22 is configured to convert the base radiation of the corresponding emitter 20 into the first, second, third or fourth radiation that the emitter 20 is configured to emit. In this case, the base mean wavelength is strictly inferior to the mean wavelength of the first, second, third or fourth radiation that the emitter 20 is configured to emit.

Many types of radiation converters are used in lighting, for example in fluorescent tubes. Such radiation converters are often called “phosphors”.

The radiation converter 22 is made of a converting material.

The converting material is configured to convert the base radiation into the third radiation.

The converting material is, for example, a semiconductor material.

According to other embodiments, the converting material is a non-semiconductor material such as a Yttrium-Aluminum garnet.

Many other converting materials may be used, such as aluminate, nitride, fluoride, sulfide or silicate materials.

The converting material is, for example, doped using rare earth, alkaline earth metal or transition metal elements.

The converting material is, for example, made of CdSe or InP.

The radiation converter 22 comprises, for example, a set of particles P made of the converting material.

Each particle P has, for example, a diameter smaller than or equal to 2 μm.

In an embodiment, each particle P is a quantum dot for charge carriers in the particle.

A quantum dot is a structure in which quantum confinement occurs in all three spatial dimensions.

An example of quantum dot is particle P having a maximal dimension inferior or equal to the product of the electronic wavelength of the charge carriers or excitons in the converting material with five.

So as to give an order of value, a particle P having a maximal dimension comprised between 1 nm and 200 nm and made of a semiconductor converter material is an example of quantum dot.

Another example of quantum dot is particle P having a core and a shell surrounding the core, the core being made of a semiconductor converter material and having a maximal dimension comprised between 1 nm and 200 nm.

The particles P are, for example, embedded in a photosensitive resin. Photosensitive resins are used in many electronic manufacturing techniques to define patterns on a semiconductor surface, in particular, since specific areas of the resin may be solidified while leaving other areas removable, in order to define the patterns. The areas to be removed or solidified are defined by insolation using a light wavelength to which the resin is sensitive. Such photosensitive rein is, in particular, used for protecting the covered areas against deposition of material or etching.

It should be noted that other types of radiation converters 22 may be considered.

The blocking structure 25 is configured to prevent at least one radiation emitted by the sub-pixel 20 to reach another sub-pixel 20 through the blocking structure 25. In particular, the blocking structure 25 is configured to prevent the first, second, third or fourth radiation emitted by the sub-pixel 20 to reach another sub-pixel 20 through the blocking structure 25, and vice-versa.

The blocking structure 25 is interposed between the sub-pixel 20 and at least one other sub-pixel 20. In particular, the blocking structure 25 is interposed between both sub-pixels 20 in the recess 95 delimited by both sub-pixels 20.

In particular, the blocking structure 25 is interposed between the sub-pixel 20 and every other sub-pixel 20. For example, the blocking structure 25 surrounds the sub-pixel 20 in a plane perpendicular to the normal direction D.

In the example of FIG. 1, the blocking structure 25 fills completely the recess 95.

The blocking structure 25 comprises a blocking layer 125.

In an embodiment, the blocking structure 25 further comprises a second barrier layer 130. In the example shown on FIG. 1, each sub-pixel 20 further comprises a top layer 135.

The blocking layer 125 is configured to prevent the first, second, third or fourth radiation emitted by the sub-pixel 20 to reach another sub-pixel 20 through the blocking structure 25, and vice-versa.

For example, the blocking layer 125 is configured to absorb the first, second, third or fourth radiation emitted by the sub-pixel 20.

The blocking layer 125 is made of a blocking material.

The blocking material is, for example, a metal. An example of metal is aluminum.

In another embodiment, the blocking layer 125 is configured to reflect the first, second, third or fourth radiation emitted by the sub-pixel 20.

For example, the blocking layer 125 comprises a Bragg reflector. A Bragg reflector is a reflector made of a stack of layers made of different materials, the difference of optical indices between the different materials causing some optical radiations to be reflected by the reflector.

In a variant, the blocking layer 125 is configured to reflect the first, second, third or fourth radiation emitted by the sub-pixel 20.

In this variant, the blocking material is, for example, an opaque material. In an embodiment, the blocking material is a photosensitive resin, such as a black or dark photosensitive resin. In another embodiment, the blocking material is a polymeric material.

In an embodiment, the blocking material is an electrically insulating material. In such an embodiment, the second barrier layer 130 is not required.

The top layer 135 is made of the blocking material.

The top layer 135 is, for example, integral with the blocking layer 125.

The top layer 135 is interposed between the top portion 120 and the first electrode 45. In particular, the top portion 120 is interposed, along the normal direction D, between the top layer 135 and the superior side 70 of the fin 35.

The top layer 135 covers, for example, entirely the top portion 120.

The top layer 135 is configured to prevent the top radiation from exiting the sub-pixel 20.

The second barrier layer 130 is interposed between the blocking layer 125 and each sub-pixel 20. For example, the second barrier layer 130 covers at least partially the second portion 115 of the covering layer 40. In particular, the second barrier layer 130 covers entirely the second portion 115. The second barrier layer 130 thus forms a barrier between the second portion 115 and the blocking layer 125.

It should be noted that embodiments wherein the second portion 115 of the covering layer 40 is electrically connected to the first electrode 45 may be considered. For example, a portion of the first electrode 45 is interposed between the second barrier layer 130 and the second portion 115.

In a case where the sub-pixel 20 is deprived of second portion 115, the second barrier layer 130 covers at least partially the second lateral side 80. In particular, the second barrier layer 130 covers entirely the second lateral side 80 and thus forms a barrier between the second lateral side 80 and the blocking layer 125.

In the example shown on FIG. 2, the second barrier layer 130 is further interposed between the top layer 135 and the top portion 120.

In an embodiment, the second barrier layer 130 further forms a barrier between the blocking layer 125 and the substrate 30. In particular, the second barrier layer 130 further forms a barrier between the blocking layer 125 and the second electrode 50 that is contained in the passage 65.

The second barrier layer 130 is made of an electrically insulating material.

For example, the second barrier layer is made of SiO₂.

Each first electrode 45 is electrically connected to the corresponding covering layer 40. For example, each first electrode 45 is in contact with the corresponding doped layer 105.

In particular, each first electrode 45 is in contact with the first portion 110 of the corresponding covering layer 40.

Each first electrode 45 is, for instance, made of a transparent electrically conductive material. Indium-tin oxide (ITO) is an example of transparent electrically conductive material.

Each first electrode 45 is, for example, common to all sub-pixels 20.

In an embodiment, the first electrode 45 is a single layer entirely covering the surfaces of the covering layers 40.

Each second electrode 50 is configured to connect electrically the control circuit 27 to the corresponding sub-pixel 20 through the substrate 30.

Each second electrode 50 is, for example, electrically connected to the corresponding fin 35.

Each second electrode 50 is made of an electrically conductive material such as a metallic material.

The control circuit 27 is configured to supply each sub-pixel 20 with an electrical current. For example, the control circuit 27 is configured to impose a voltage between both electrodes 45, 50 of each sub-pixel 20.

The control circuit 27 is configured to supply each two-dimensional structure with an electrical current.

A first example of carrying out method for fabricating the optoelectronic device 15 is shown on FIGS. 2 to 4.

The first example of method for fabricating the optoelectronic device 15 comprises a step 200 for supplying, a step 210 for fabricating, a step 220 for depositing, a step 230 for contacting and a step 240 for placing.

During the step for supplying 200, the substrate 30 is supplied.

For example, the support plate 55 is supplied, and the first barrier layer 60 is formed onto the support face 53.

The first barrier layer 60 is, for example, fabricated by depositing the corresponding electrically insulating material onto the support face 53.

During the step for fabricating 210, each sub-pixel 20 is fabricated.

For example, the step for fabricating 210 comprises a step 250 for fabricating the fins 35 and a step 260 for depositing the covering layer 40.

During the step 250 for fabricating the fins 35, the fins 35 of each sub-pixel 20 are fabricated.

For example, each fin 35 is fabricated by depositing the first semiconductor material onto the support plate 55. The deposition is, for example, performed using a deposition technique such as Metal-Organic Chemical Vapor Deposition (MOCVD) or Molecular-Beam Epitaxy.

In a variant, each fin 35 is formed by depositing a layer of the first material onto the substrate 30 and by etching away a portion of the layer of first material to define the fins 35.

At the end of the step 250 for fabricating the fins 35, each fin 35 is in contact with the support plate 55, as shown on FIG. 2.

For example, the first barrier layer 60 is partially removed prior to depositing the first semiconductor material so that the fins 35 are formed in the areas devoid of the electrically insulating material.

During the step 260 for depositing the covering layer 40, each covering layer 40 is formed. For example, layers of the second semiconductor material and the third semiconductor material are deposited onto the first lateral side 75 of each fin 35 to form the radiation-emitting layer or layers 100 and the doped layer 105.

In an embodiment, layers of the second semiconductor material and the third semiconductor material are deposited onto the second lateral side 80 of each fin 35 to form the radiation-emitting layer or layers 100 and the doped layer 105.

Layers of the second semiconductor material and the third semiconductor material are further deposited onto the superior side 70 of each fin 35 to form the radiation-emitting layer or layers 100 and the doped layer 105.

The deposition of the second semiconductor material and the third semiconductor material is, for example, performed simultaneously onto the first lateral side 75, the second lateral side 80 and the superior side 70 of each fin 35.

During the step for depositing 220, each blocking structure 25 is fabricated.

The step for depositing 220 comprises, for example, a first step 270 for depositing and a second step 280 for depositing.

During the first step for depositing 270, the second barrier layer 130 is formed.

For example, the second barrier layer 130 is formed by depositing the corresponding electrically insulating material in the recess 95.

In an embodiment, the entire surface of the recess 95 is covered with the electrically insulating material.

In particular, the electrically insulating material is deposited onto the portion of the substrate 30 that defines the bottom of the recess 95.

In a specific embodiment, the whole surface of the substrate 30, the fins 35 and the covering layers 40 are covered with the electrically insulating material, as shown on FIG. 3. The electrically insulating material that covers the first lateral sides 75 is then removed.

During the second step for depositing 280, the blocking material is deposited in the recess 95 to form the blocking layer 125.

Possible deposition techniques for depositing the blocking material include sputter coating, plasma vapour deposition, chemical vapour deposition, thermal evaporation, electron-beam evaporation, spin-coating and spray coating, among others.

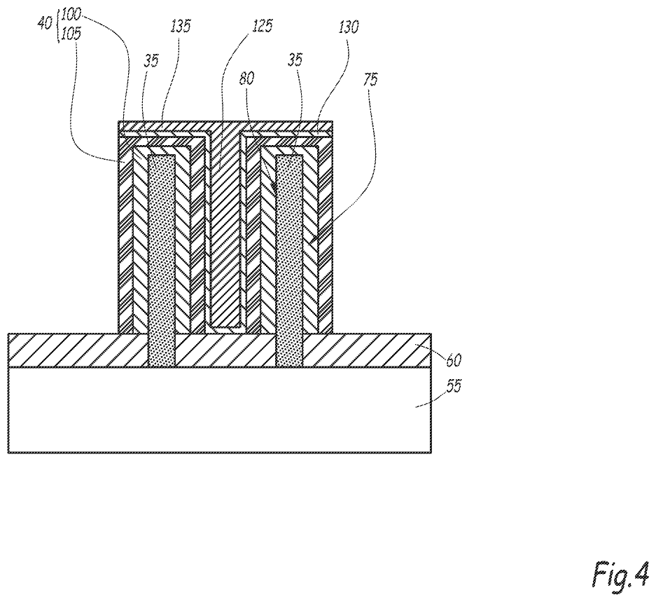

The top layer 135 is also formed by depositing the blocking material on the top portion 120 of the covering layer 40, as visible on FIG. 4.

During the step for contacting 230, the first and second electrodes 45, 50 are formed.

For example, the first electrode 45 is formed by depositing a layer of transparent conducting material onto at least the covering layer 40 of each sub-pixel 20 to form the first electrode 45.

Each passage 65 is formed into the support plate 55, for example by etching.

The electrically insulating material that forms the portion of the first barrier layer 60 that is contained in the passage 65 is then deposited into the passage 65.

Each second electrode 50 is formed by depositing, into the passage 65, an electrically conductive material such as a metal.

Each second electrode 50 is then electrically connected to the control circuit 27 to obtain the optoelectronic device 15 of FIG. 1.

During the step for placing 240, each radiation converter 22 is placed in the vicinity of the corresponding sub-pixel 20.

Thanks to the use of the blocking structure 25, optical cross-talk between neighboring emitters 20 is prevented, even when the sub-pixels 20 are very close to one another. The dimensions of the optoelectronic device 15 may therefore be reduced with respect to existing optoelectronic devices.

Thanks to the first barrier layer 60, electrical losses between the covering layer 40 and the substrate 30 are prevented.

Connecting the sub-pixels 20 to the control circuit 27 through the substrate 30 allow for an improved overall useful surface for the optoelectronic device, since no part of the support face 30 is covered by the control circuit 27. The dimensions of the display screen 10 may therefore be reduced.

Having a two-dimensional semiconductor structure integrated in the substrate 30 allows for an even more compact disposition of the optoelectronic devices 15, since less sub-pixels 20 are required for each optoelectronic device 15, the role of one of the sub-pixels 20, for example the red-emitting sub-pixel 20, being taken by the two-dimensional semiconductor structure.

When the blocking layer 125 is able to reflect the first, second, third or fourth radiation of each sub-pixel 20, the reflected first, second, third or fourth radiation has a strong chance of exiting the sub-pixel. The overall emission efficiency of the sub-pixel is thus improved.

If the base radiation is reflected, the reflected base radiation has a chance of attaining the radiation converter 22 and to be converted into the first, second, third or fourth radiation of the sub-pixel 20. The emission efficiency is therefore also improved.

Metallic blocking layers 125 are very stable in time and reflect efficiently many types of radiations.

An aluminum blocking layer 125 is easy to deposit without damaging the existing semiconductor structures.

A blocking layer 125 made of photosensitive resin or polymer is easy to deposit precisely using commonly-used techniques. Furthermore, since these materials are electrically insulating, the method for fabricating the optoelectronic device 15 is simpler since the second barrier layer 130 is not required.

If a top portion 120 of the covering layer 40 is present in a sub-pixel, this top portion may emit a different wavelength than the lateral portions 110, 115. The top portion may thus be used as a sub-pixel, thus removing the need for one of the sub-pixels 20 in the optoelectronic device 15 and allowing for a more compact disposition on the substrate 30.

The formation of the top portion 120 is sometime difficult to avoid during the fabrication of the emitter. The top layer 135 efficiently prevents any light emitted by the top portion 120 to exit the sub-pixel 20 if this light is not desired.

The formation of a second lateral portion 115 may also be undesired. The second barrier layer 60 prevents this second portion to be supplied with an electrical current, and thus improves the overall emission efficiency of each sub-pixel 20.

The second barrier layer 60 also prevents current leakage between two neighboring sub-pixels 20 through the blocking structure 25.

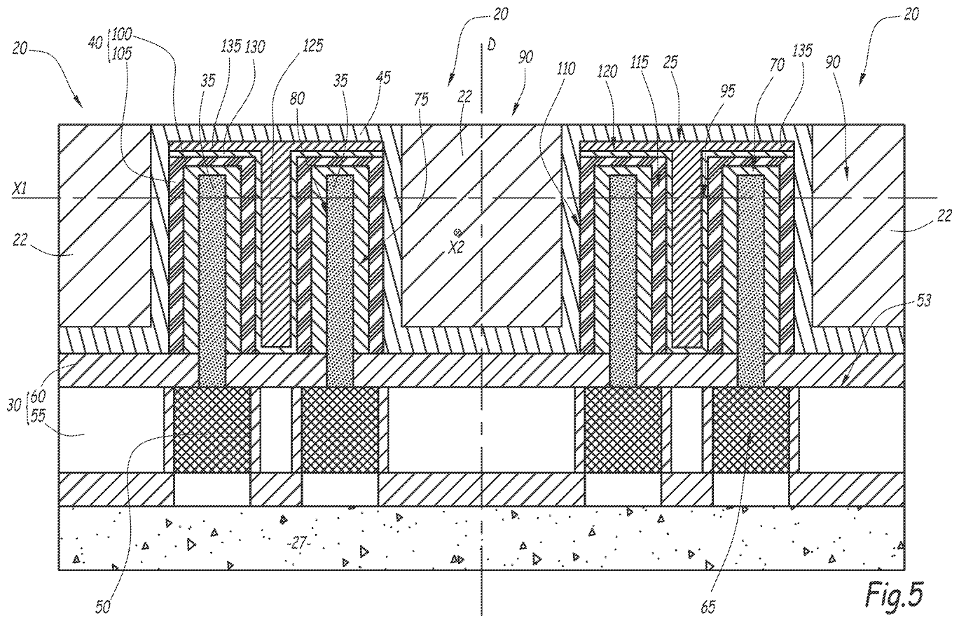

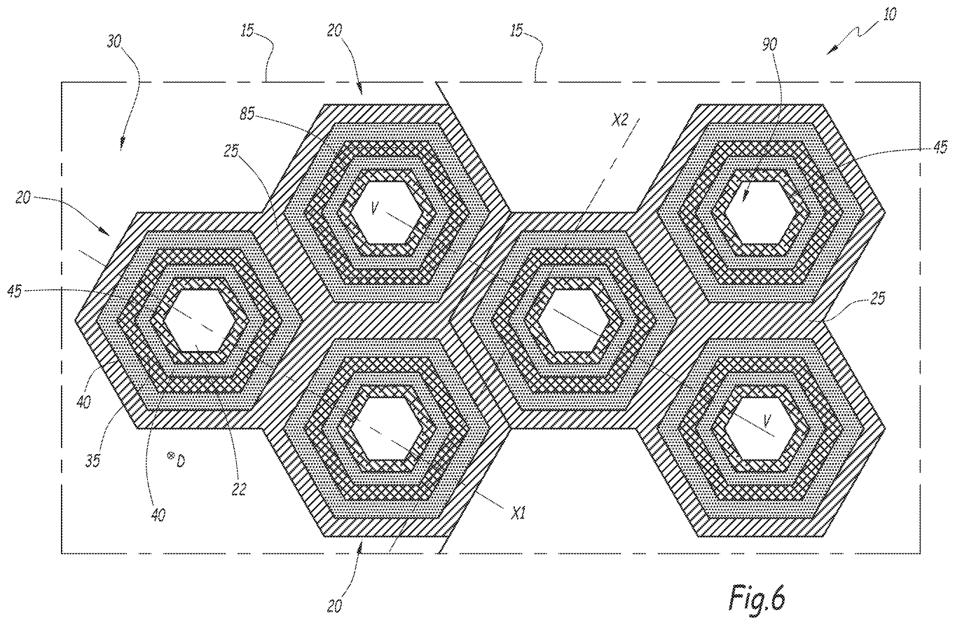

In an embodiment shown on FIGS. 5 and 6, the intersections of each fin 35 of each sub-pixel 20 with the support face 53 form a closed contour 85.

The closed contour 85 is, for example, a polygon. Examples of polygons are a triangle, a square, a rectangle and a hexagon.

In the example shown on FIG. 6, the contour 85 is a hexagon. In this case, each sub-pixel 20 comprises a single fin 35, the fin 35 being annular and having an hexagonal cross-section in a plane perpendicular to the normal direction D. In another interpretation, the hexagonal fin 35 may also be considered as being made of an ensemble of six parallelepiped fins.

In other embodiments, the fin 35 may be annular with a square, triangular or rectangular cross-section.

Other non-polygonal contours 85 may be envisioned. For example, the contour 85 is a circle.

The fin or fins 35 of each sub-pixel 20 delimit a cavity 90.

The cavity 90 is, for example, delimited along the first direction X1 by two opposite inner faces of the fin or fins 35, the inner faces being parallel to each other.

When the fins of one sub-pixel 20 form a closed contour 85, the cavity 90 is surrounded in a plane perpendicular to the normal direction D by the fin or fins 35.

The cavity 90 is, for example, delimited along the normal direction D by the substrate 30. In the embodiment shown on FIG. 5, part of the first electrode 45 is interposed between the cavity 90 and the substrate 30.

The first portion 110 is interposed between the first lateral side 75 and the cavity 90.

The blocking layer 125 surrounds, for example, each sub-pixel 20 in a plane perpendicular to the normal direction D.

In the example shown on FIG. 5, the recess 95 surrounds the sub-pixel 20 in a plane perpendicular to the normal direction D. In that case, a single recess 95 is delimited by all sub-pixels 20 and is interposed between each sub-pixel 20 and each other sub-pixel 20. For example, all recesses 95 communicate with each other and the blocking structure 25 is common to all sub-pixels 20, as shown on FIG. 6.

On FIG. 6, two optoelectronic devices 15 comprising each three sub-pixels 20 are shown.

Each radiation converter 22 is contained in the cavity 90 of the corresponding sub-pixel 20.

In an embodiment, the radiation converter 22 fills the cavity 90 up to at least half of the height of the fin 35. For example, the radiation converter 22 fills the cavity 90 entirely.

In a variant, each particle P is attached to a portion of the first electrode 45. For example, each particle P is attached to a portion of the first electrode 45 that is contained in the cavity 90.

For example, a surface of the first electrode 45 is at least partially covered with a layer of particles P.

Each particle P is, for example, attached to the surface of the first electrode 45 by grafting.

Grafting is a method for attaching particles P to a surface, wherein the surface is functionalized using molecules M attached to the surface and able to allow each particle P to attach to the surface through the molecule M. In particular, one extremity of each molecule M is able to attach to a surface of the first electrode 45 and another extremity is able to attach to a particle P of converting material so that the particle P is attached to the first electrode 45 by the molecule M.

The radiation converter 22 comprises, for example, a grafting layer made of the molecules M, the layer being attached to the surface of the first electrode 45 by the grafting layer.

Each radiation converter 22 is placed in the corresponding cavity 90 during a step for placing 240. The step for placing 240 is, for example, performed after the step for contacting 230.

By converting a radiation that is efficiently emitted by the semiconductor structure into the desired radiation, radiation converter 22 allows for an efficient overall emission even if known semiconductor structures are not efficient at the desired wavelength.

Furthermore, using different radiation converters 22 from one sub-pixel 20 to another allows for the semiconductor structure (i.e each fin 35 and covering layer 40) of each sub-pixel 20 to be identical to the semiconductor structure of the other sub-pixels 20. The fabrication of the sub-pixels 20 is therefore easier.

Placing the radiation converter 22 in the cavity 90 allows for a more precise placement, since the radiation converter 22 is contained laterally by the fin or fins 35, thus reducing risk that radiation converter 22 overspills or spreadsoutside of the area where the radiation converter 22 is meant to be placed.

This placement is all the more precise when the cavity is surrounded by the fin or fins 35 in a plane perpendicular to the normal direction D.

Polygonal contours 85 are easy to fabricate and allow for a very high filling factor of sub-pixels 20 on the support face 53. In particular, hexagonal contours allow for a very compact disposition of sub-pixels 20 on the substrate 30.

A second example of method for fabricating the optoelectronic device 15 will now be described. All steps identical to those of the first example of method are not described again. Only the differences are detailed in the following.

The step for fabricating 210 comprises a step for fabricating a ridge, the step 260 for depositing the covering layer 40 and a step 270 for etching.

At least one ridge 300 made of the first material is fabricated onto the substrate 30. In particular, one ridge 300 is fabricated for each pair of fins 35 delimiting a recess 95.

The ridge 300 corresponds to two fins 35 and to the recess 95 delimited by the two fins 35. The two lateral sides 75 of the ridge 300 are thus the lateral sides 75 of the fins 35 corresponding to the ridge 300. The superior side of the ridge 300 corresponds to the superior sides 70 of both fins 35.

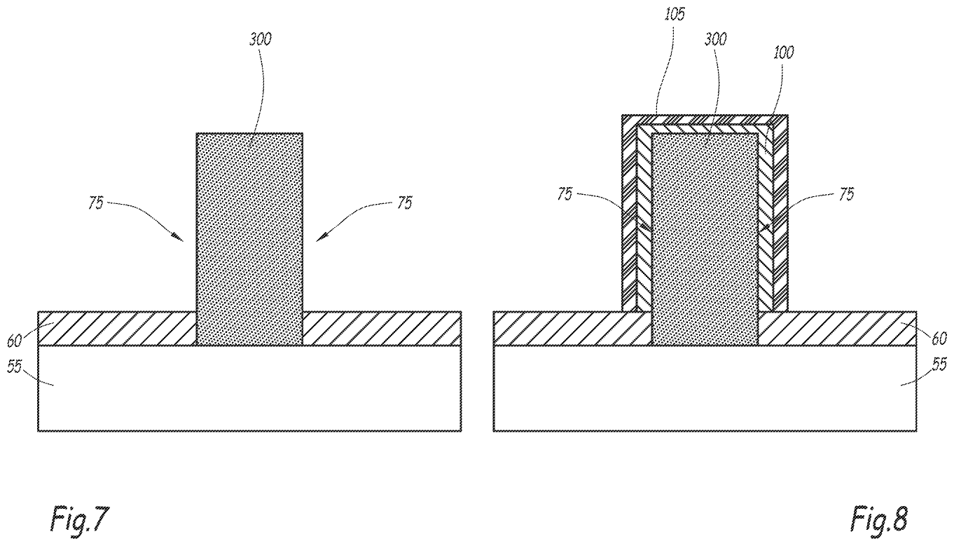

The ridge 300 is shown on FIG. 7.

In an embodiment, all the ridges 300 are connected to each other to form a beehive structure on the substrate 30.

The ridge 300 extends from the support face along the normal direction D.

The ridge 300 has a superior side 70 and two first lateral sides 75.

Each ridge 300 is, for example, a parallelepiped. Each side 70, 75 of the ridge 300 is then perpendicular or parallel to the normal direction D.

Each ridge 300 has a thickness measured along the second direction X2 defined for the two corresponding fins 35. The thickness of the ridge 300 is equal to the sum of the thicknesses of the fins 35 and of the width of the recess 95 interposed between those fins 35.

During the step 260 for depositing the covering layer 40, the first portion 110 of the covering layer 40 is deposited onto at least one of the first lateral sides 75 of the ridge 300. In particular, the first portion 110 of the covering layer 40 is deposited onto both first lateral sides 75 of the ridge 300, as shown on FIG. 8.

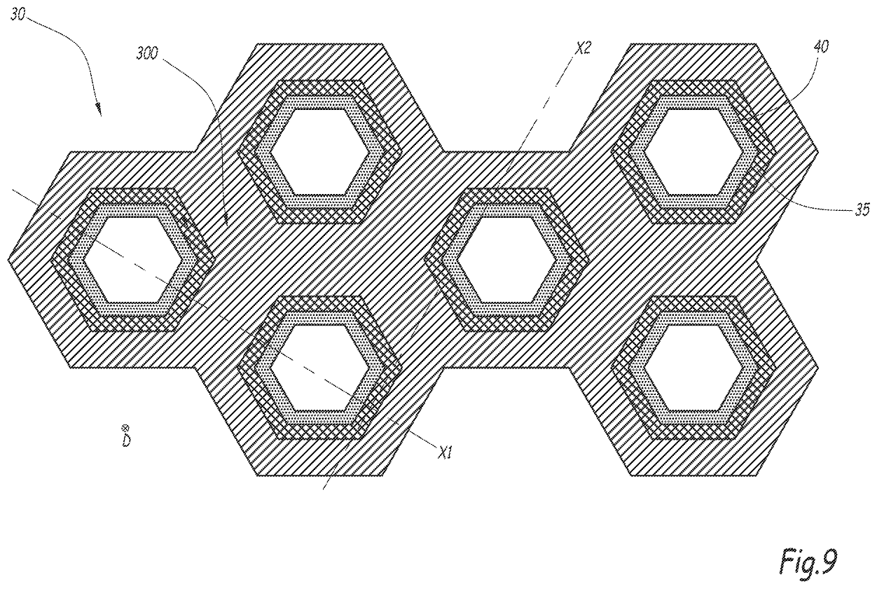

An example of an ensemble of ridges 300 and first portions 110 is shown on FIG. 9. This example is an example of the ridges 300 and first portions 110 at the end of the step 260 for depositing the covering layer 40.

In an embodiment, the top portion 120 of each covering layer 40 is further deposited onto the superior side 70 of each ridge 300.

During the etching step, a portion of each ridge 300 is removed to define the recess 95. In particular, a portion of the ridge 300 is removed by etching.

The recess 95 and the fins 35 are thus defined.

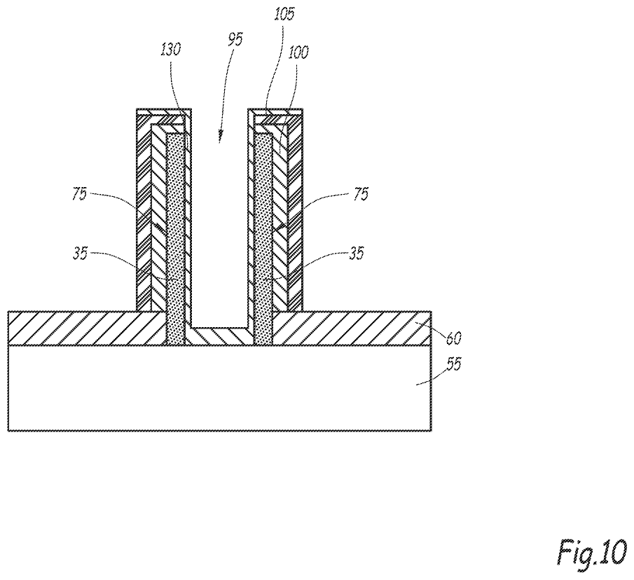

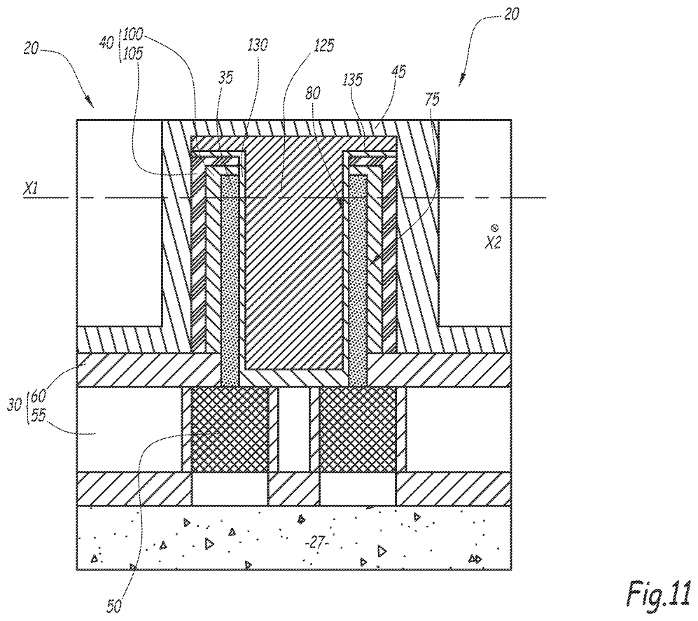

The etching step is followed by the step 220 for depositing, during which the second barrier layer 130 is formed in the recess 95, as shown on FIG. 10.

In this second example, the sub-pixels 20 obtained are deprived of a second portion 115. The optoelectronic device 15 thus obtained is shown on FIG. 11.

The sub-pixels 20 have been described in the examples above as having lateral sides 75, 80 perpendicular to the substrate 30. However, lateral sides 75, 80 that are not perpendicular to the substrate 30 may be considered.

In an example, each fin 35 has a trapezoidal cross-section along the second direction X2.

Each of the semiconductor materials described above may be chosen among a great number of semiconductor materials.

For example, any one of the first, second and third semiconductor material or the substrate material may be chosen among arsenide materials such as AlAs, GaAs, InAs, among phosphide materials such as AlP, GaP, InP, among II-VI materials such as ZnSe, CdSe, ZnTe, CdTe, among IV-materials such as Si and Ge, among III-nitride materials or among any alloy of such materials.

A third example of method for fabricating the optoelectronic device 15 will now be described. All steps identical to those of the first example of FIGS. 2 to 4 are not described again. Only the differences are detailed in the following.

During the step for fabricating the fins 250, a core 305 made of a core material is deposited onto the substrate 30 for each cavity 90. For example, the core material is deposited by MOCVD, MBE, vapour-liquid-solid growth or another deposition method.

Each core 305 has a shape corresponding to the shape of the corresponding cavity 90.

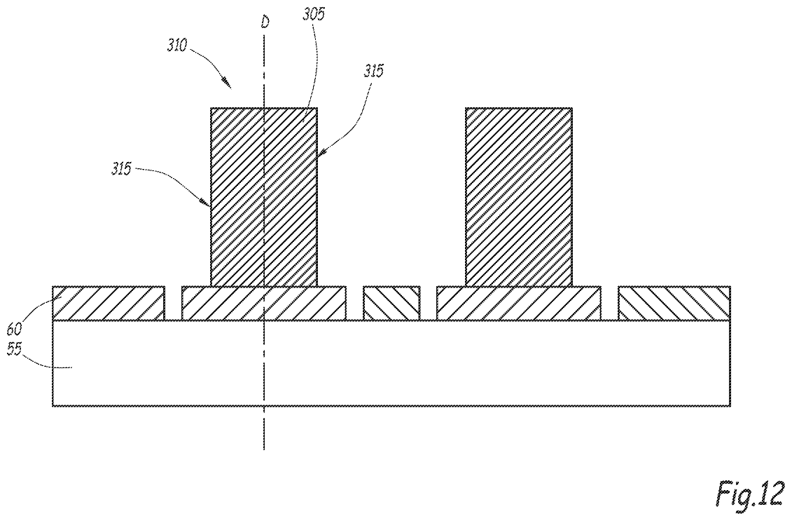

The core 305 extends from the support face 53 along the normal direction D, as shown on FIG. 12.

The core 305 has a superior face 310 and lateral flanks 315 extending between the substrate 30 and the superior face 310.

The core 305 is, for example, a cylindrical core having a polygonal base. In this case, the lateral flanks 315 are formed by the reunion of an ensemble of rectangular plane faces, each face extending along the normal direction D.

The intersection of the lateral flanks 315 with the substrate 30 forms the closed contour 85.

The core material is, for example, ZnO. However, other core materials may be considered.

Each fin 35 is formed by depositing the first semiconductor material onto the lateral flanks 315. Each fin 35 is, for example, formed by MOCVD, MBE of another material deposition method.

Each fin 35 surrounds the corresponding core 305 in a plane perpendicular to the normal direction D. In particular, each first lateral side 75 is delimited by the core 305.

The core 305 is then removed before the step for depositing 260.

The core 305 is, for example, dissolved. An example of method for dissolving the core is to dip the substrate 30 in a liquid adapted to dissolve the core material.

Another method for dissolving the core 305 is to heat the substrate 30, the fins 35 and the corresponding cores 305 to a temperature able to provoke the dissolution of the cores 305.

In another embodiment, the covering layer 40 is deposited onto at least one lateral side of the fin 35 before dissolving the core 305.

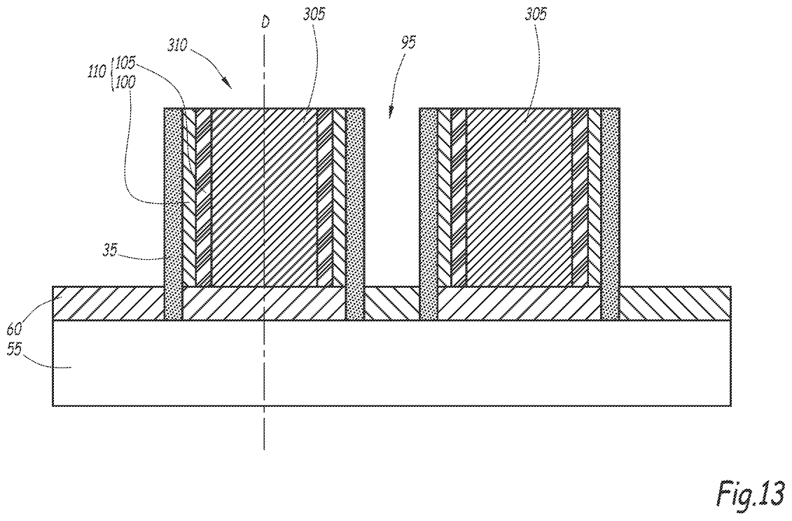

For example, at least one layer of the second semiconductor material is deposited onto the lateral flanks. In particular, the second and third material forming the first portion 110 of the covering layer 40 are deposited onto the core before the first material forming the fin 35 is deposited, as shown on FIG. 13.

In an embodiment, the second and third material forming the second portion 115 and the top portion 120 of the covering layer 40 are then deposited onto the fin 35 before the core 305 is removed.

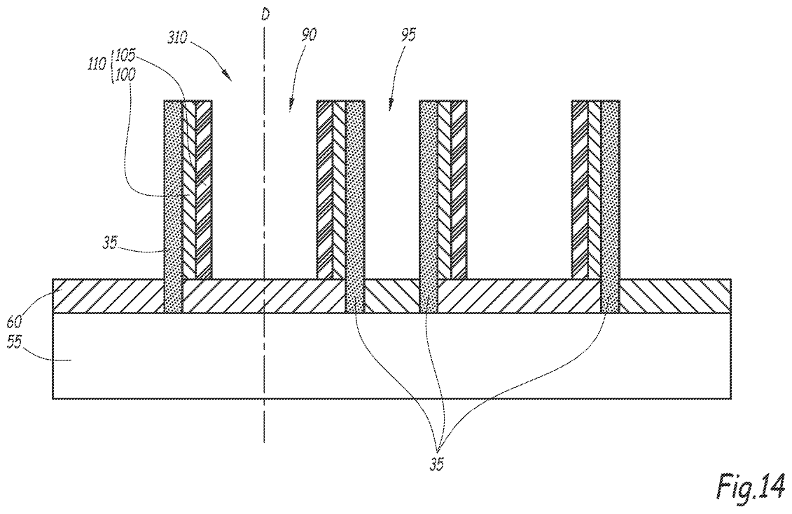

As shown on FIG. 14, the volume where the core 305 stood forms the corresponding cavity 90 after dissolving of the core 305.

The third method does not require etching away very precisely part of a ridge 300, and is thus simpler that the second method.

When the core is made of ZnO, the core may be efficiently removed by heating at a temperature that is low enough to leave the other materials of the optoelectronic device 15, notably III-nitride or silicon semiconductors, undamaged.

Embodiments wherein the contour 85 is not closed may also be envisioned.

In an embodiment, the contour 85 is U-shaped, for example when the fin 35 has a U-shaped cross-section in a plane perpendicular to the normal direction D. In this case, the cavity 90 is delimited on three sides by the fin 35.

In another embodiment, the sub-pixel comprises two parallelepiped fins 35 delimiting between them the cavity 90. The cavity is interposed between both fins 35 along the first direction X1. In this case, the cavity 90 is delimited along the first direction X1 by the fins 35 of the sub-pixel 20.

1. An optoelectronic device comprising a substrate and at least two sub-pixels, each sub-pixel being adapted to emit a respective first radiation, the substrate having a support face, each sub-pixel comprising:
at least one fin made of a first semiconductor material, the first material having a first bandgap value, the fin extending from the support face along a normal direction perpendicular to the support face, each fin having a superior side, a first lateral side and a second lateral side, each lateral side extending between the superior side and the substrate,
a covering layer comprising one or several radiation-emitting layer(s), the covering layer extending on the first lateral side of each fin, each radiation-emitting layer being made of a second semiconductor material, the second semiconductor material having a second bandgap value, the second bandgap value being strictly inferior to the first bandgap value,
the sub-pixels delimiting a recess, the recess being located between both sub-pixels, and a blocking structure made of a third material being interposed between both sub-pixels in the recess, the blocking structure being adapted to prevent the first radiation emitted by a sub-pixel to reach the other sub-pixel through the blocking structure.

2. The optoelectronic device according to claim 1, wherein at least one of the following properties is fulfilled:
the first semiconductor material has a first type of doping chosen among n-doping and p-doping, the covering layer further comprising a doped layer, each radiation-emitting layer(s) being interposed between the fin and the doped layer, the doped layer being made of a third semiconductor material having a third bandgap value, the third bandgap value being strictly greater than the second bandgap value, the third semiconductor material having a second type of doping chosen among n-doping and p-doping, the second type of doping being different from the first type of doping,
the optoelectronic device comprises a control circuit and, for at least one sub-pixel, an electrode connecting the sub-pixel and the control circuit through the substrate, and
at least one sub-pixel comprises a first barrier layer made of an electrically insulating material, the first barrier layer forming a barrier between the substrate and the covering layer.

3. The optoelectronic device according to claim 1, wherein each fin of each sub-pixel delimits at least partially a cavity in a plane perpendicular to the normal direction.

4. The optoelectronic device according to claim 3, wherein the intersections of the each fin of one sub-pixel with the support face forming a closed contour on the support face, the cavity being surrounded by the fin in a plane perpendicular to the normal direction.

5. The optoelectronic device according to claim 4, wherein the contour is chosen among a triangle, a square, a rectangle and a hexagon.

6. The optoelectronic device according to claim 3, wherein each first radiation comprises a first set of electromagnetic waves, the radiation-emitting layer of at least one sub-pixel being configured to emit a second radiation comprising a second set of electromagnetic waves, the optoelectronic device further comprising a radiation converter configured to convert the second radiation into the respective first radiation, a wavelength being defined for each electromagnetic wave, the first set corresponding to a first range of wavelengths and the second set corresponding to a second range of wavelengths, the first range having a first mean wavelength and the second range having a second mean wavelength, the first mean wavelength being different from the second mean wavelength, the radiation converter being contained in the cavity of the sub-pixel considered.

7. The optoelectronic device according to claim 6, wherein the blocking structure is adapted to reflect the base radiation of each sub-pixel.

8. The optoelectronic device according to claim 1, wherein the substrate comprises a semiconductor structure configured to emit a third radiation comprising a third set of electromagnetic waves, a wavelength being defined for each electromagnetic wave, the first set corresponding to a first range of wavelengths and the third set corresponding to a third range of wavelengths, the first range having a first mean wavelength and the third range having a third mean wavelength, the first mean wavelength being strictly inferior to the third mean wavelength, the semiconductor structure and at least one sub-pixel being aligned along the normal direction.

9. The optoelectronic device according to claim 1, wherein at least one of the following properties is fulfilled:
each covering layer is in contact with at least ninety percent of the surface of the first lateral side of the fin,
the third material is a metal, and
the third material is aluminum.

10. The optoelectronic device according to claim 1, wherein the blocking structure is adapted to reflect the first radiation of each sub-pixel.

11. The optoelectronic device according to claim 1, wherein each covering layer has a top portion in contact with the superior side and a first portion in contact with the first lateral side.

12. The optoelectronic device according to claim 11, wherein at least one blocking structure has a top layer made of the third material, the top portion being interposed between the superior side of the fin and the top layer, the top layer covering entirely the top portion of the covering layer.

13. The optoelectronic device according to claim 11, wherein each first radiation comprises a first set of electromagnetic waves, the top portion a the radiation-emitting layer being configured to emit a fourth radiation comprising a fourth set of electromagnetic waves, a wavelength being defined for each electromagnetic wave, the first set corresponding to a first range of wavelengths and the fourth set corresponding to a fourth range of wavelengths, the first range having a first mean wavelength and the fourth range having a fourth mean wavelength, the first mean wavelength being different from the fourth mean wavelength.

14. The optoelectronic device according to claim 1 wherein:
each covering layer has a second portion covering at least partially the second lateral side of the corresponding fin, and
the blocking structure comprises an electrically insulating layer configured to electrically isolate at least one sub-pixel from the blocking structure.

15. A display screen comprising a set of optoelectronic devices according to claim 1.

16. A method for fabricating an optoelectronic device, the method comprising steps for:
supplying a substrate having a support face, and
fabricating two emitters, each sub-pixel being adapted to emit a corresponding first radiation, each sub-pixel comprising:
at least one fin made of a first semiconductor material, the first material having a first bandgap value, the fin extending from the support face along a normal direction perpendicular to the support face, each fin having a superior side, a first lateral side and a second lateral side, each lateral side extending between the superior side and the substrate, and
a covering layer comprising one or several radiation-emitting layer(s), the covering layer extending on the first lateral side of each fin, each radiation-emitting layer being made of a second semiconductor material, the second semiconductor material having a second bandgap value, the second bandgap value being strictly inferior to the first bandgap value,
both sub-pixels delimiting a recess between both sub-pixels the method further comprising a step for depositing, in the recess, a third material so as to form a blocking structure adapted to prevent the first radiation emitted by a sub-pixel to reach the other sub-pixel through the blocking structure.

17. The method according to claim 16 wherein the step for fabricating two sub-pixels comprises steps for:
fabricating one ridge made of the first semiconductor material, the ridge extending from the support face along the normal direction, the ridge having a superior side and two first lateral sides,
depositing the covering layer on at least the two first lateral sides of the ridge, and
forming the fins and the recess by etching away at least a portion of the ridge.

18. The method according to claim 16, wherein the step for fabricating two sub-pixels comprises steps for:
forming a core made of a fourth material, the core extending from the support face along the normal direction, the core having a superior face and lateral flanks extending between the substrate and the superior face,
depositing a layer of the first material and at least one layer of the second material on at least a portion of the lateral flanks to form at least one fin and the corresponding covering layer, and
removing the fourth material.

19. The method according to claim 16, wherein the step for fabricating two sub-pixels comprises steps for:
fabricating the fin of each sub-pixel, and
depositing on each fin at least one layer of the second material to form the covering layer.

20. The method according to claim 16, further comprising at least one of the following steps:
depositing, onto the covering layer of at least one sub-pixel, a layer of transparent electrically conductive material,
depositing onto the support face a first barrier layer made of electrically insulating material, the first barrier layer forming a barrier between the covering layer and the substrate, and
before depositing the third material, depositing in the recess an electrically insulating material so as to form a second barrier layer made of electrically insulating material onto at least one sub-pixel, the second barrier layer forming a barrier between the third material and the sub-pixel.
